(19) United States
(12) Patent Application Publication
(10) Pub. No.: US 2026/0173632 A1
(43) Pub. Date: Jun. 18, 2026

(54) DISPLAY PANEL

(71) Applicant: PlayNitride Display Co., Ltd., MiaoLi County (TW)

(72) Inventors: Hao-Yun Lai, MiaoLi County (TW); Han-Cheng Tsou, MiaoLi County (TW)

(73) Assignee: PlayNitride Display Co., Ltd., MiaoLi County (TW)

(21) Appl. No.: 19/073,012

(22) Filed: Mar. 7, 2025

(30) Foreign Application Priority Data
Dec. 16, 2024 (TW) 113148915

(51) Int. Cl. H10H 29/856; H10H 29/85

(52) U.S. Cl. CPC H10H 29/856; H10H 29/8506

(57) ABSTRACT

A display panel includes a display substrate, a reflective structure, micro-light-emitting elements, refractive structures and a light transparent structure. The reflective structure is disposed on the display substrate, and defines a surface of the display substrate as pixel areas. Each of the micro-light-emitting elements is disposed on one of the pixel areas and has an upper surface away from the display substrate. The upper surface defines a central area and a peripheral area surrounding the central area. Each of the refractive structures covers the peripheral area of one of the micro-light-emitting elements and exposes the central area of the one of the micro-light-emitting elements to form a notch. The light transparent structure covers the refractive structures and the micro-light-emitting elements. The light transparent structure fills each of the notches and contacts each of the central areas, and a refractive index of the light transparent structure is smaller than a refractive index of the refractive structure.

### CROSS-REFERENCE TO RELATED APPLICATION

The application claims the priority benefit of Taiwan application serial no. 113148915, filed on Dec. 16, 2024. The entirety of the above-mentioned patent application is hereby incorporated by reference herein and made a part of the specification.

### BACKGROUND

### Technical Field

The present invention relates to a display panel, and particularly relates to a display panel that has improved light extraction efficiency and emits light uniformly.

### Related Art

In current display panels, the light emitting element (such as an LED chip) is covered by an encapsulating colloid on top. Since the refractive index of the light emitting element is greater than that of the encapsulating colloid, the surface of the light emitting element is usually roughened to reduce the occurrence of total internal reflection. The roughening treatment causes the light extraction angle of the light emitting element to be uniformly distributed, resulting in some large-angle rays still experiencing total internal reflection when leaving the light emitting element and re-entering the encapsulating material or air.

A common solution currently is to place a lens above the light emitting element to converge the rays, but the process of placing the lens encounters many challenges (such as insertion failure or misalignment of the lens relative to the light emitting element), resulting in limited effect of converging rays by using the lens, or inconsistent convergence effects between pixels. This may cause non-uniform light extraction from the display panel and lower light extraction efficiency.

### SUMMARY

The present invention provides a display panel that has improved light extraction efficiency and emits light uniformly.

A display panel of the present invention includes a display substrate, a reflective structure, micro light emitting elements, refractive structures, and a light transparent structure. The reflective structure is disposed on the display substrate, and the reflective structure divides the surface of the display substrate into multiple pixel areas. Each micro light emitting element is disposed in one of the pixel areas, and each micro light emitting element has an upper surface on the side away from the display substrate, the upper surface defining a central area and a peripheral area surrounding the central area. Each refractive structure covers the peripheral area of the one of the micro light emitting elements, and exposes the central area of the micro light emitting element therein to form a notch. The light transparent structure covers the refractive structures and the micro light emitting elements, the light transparent structure fills each notch and contacts each central area, and the refractive index of the light transparent structure is smaller than the refractive index of the refractive structure. Each refractive structure has a contact surface contacting the light transparent structure on the side away from the corresponding peripheral area, and an acute angle is included between each contact surface and the upper surface of the corresponding micro light emitting element.

Based on the above, the notch design of the refractive structure in the display panel of the present invention may allow rays emitted from the central area of the micro light emitting element, if having a very small divergence angle, not to enter the refractive structure, which may avoid the problem of rays with very small divergence angles being refracted and diverged by the refractive structure. Furthermore, the notch design of the refractive structure may allow rays with large divergence angles in the central area to enter the refractive structure, causing the rays to undergo secondary refraction in the refractive structure before being emitted towards the reflective structure, which may lower the height position where the rays are incident on the reflective structure, thereby reducing the height requirements for the reflective structure. In addition, the light reflected by the reflective structure may be emitted towards the front of the micro light emitting element, which may improve light extraction efficiency. As the light extraction efficiency of each micro light emitting element in the display panel is effectively improved, the uniformity of light extraction from the display panel may be increased.

### BRIEF DESCRIPTION OF THE DRAWINGS

FIG. 1 is a partial top view illustrating a display panel according to an embodiment of the present invention.

FIG. 2A is a cross-sectional view along line A-A in FIG. 1.

FIG. 2B is a diagram illustrating one of the ray paths in FIG. 2A.

FIG. 2C is an enlarged partial view of FIG. 2A.

FIG. 3A is a partial cross-sectional view illustrating a display panel according to another embodiment of the present invention.

FIG. 3B and FIG. 3C are partial cross-sectional views illustrating various refractive structures according to another embodiments of the present invention.

FIG. 4A is a partial cross-sectional view illustrating a display panel according to another embodiment of the present invention.

FIG. 4B is a diagram illustrating the ray paths of the refractive structure in FIG. 4A comparing different curved contact surfaces.

FIG. 5 is a partial cross-sectional view illustrating a display panel according to another embodiment of the present invention.

### DESCRIPTION OF THE EMBODIMENTS

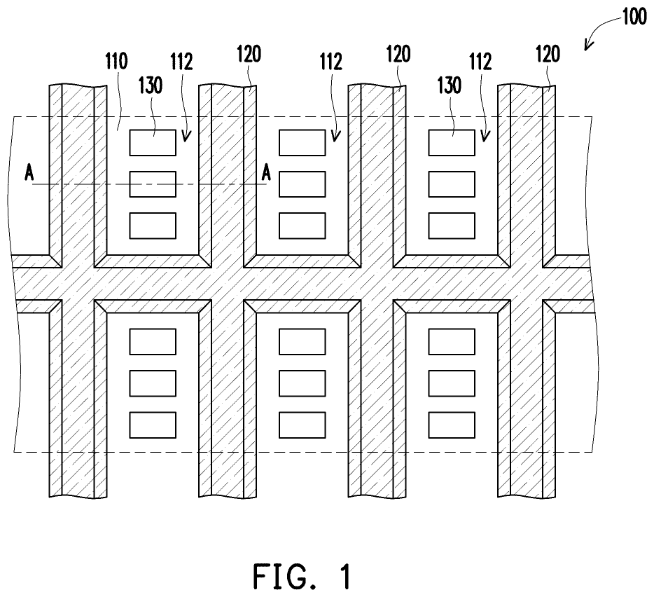

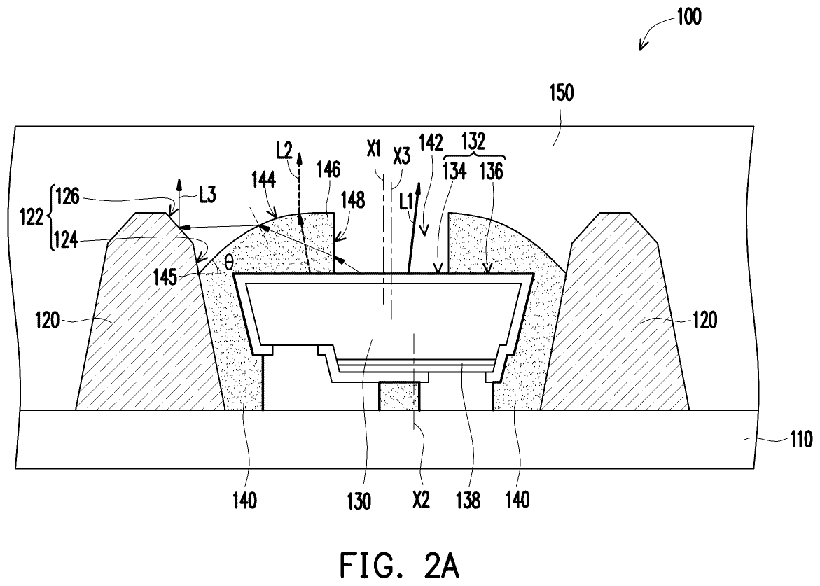

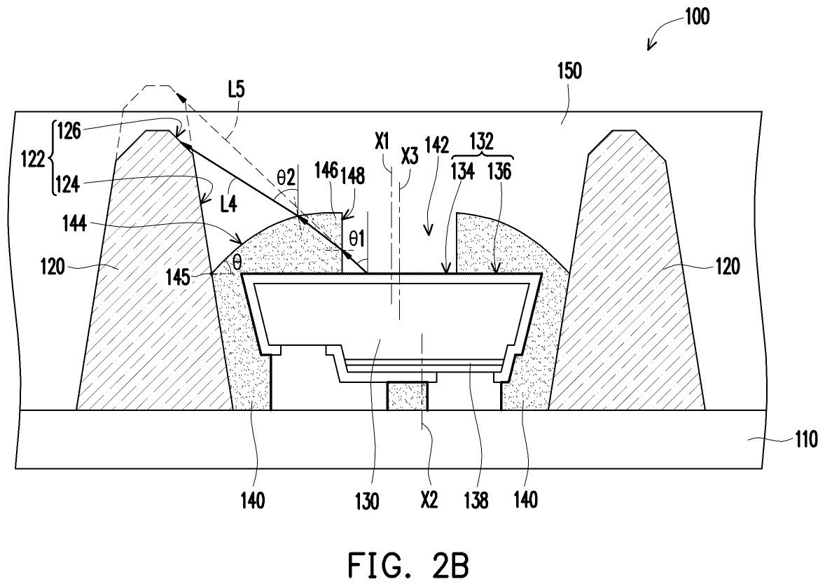

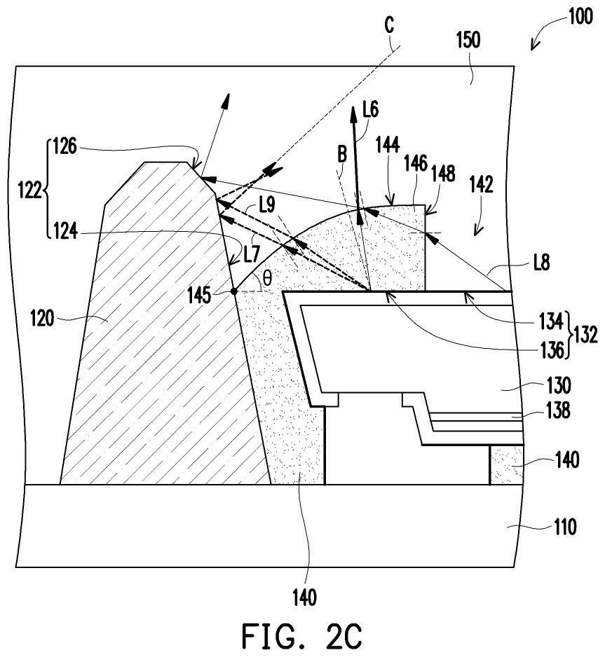

FIG. 1 is a partial top view illustrating a display panel according to an embodiment of the present invention. FIG. 2A is a cross-sectional view along the A-A line segment in FIG. 1. It should be noted that, for the sake of clarity, the refractive structure 140 and the light transparent structure 150 are omitted in FIG. 1. FIG. 2A only shows one micro light-emitting element 130 and its corresponding structure, but other micro light-emitting elements 130 and their corresponding structures in FIG. 1 may also be as shown in FIG. 2A.

Please refer to FIG. 1 and FIG. 2A, the display panel 100 of the embodiment includes a display substrate 110, a reflective structure 120, multiple micro light-emitting elements 130, multiple refractive structures 140 (FIG. 2A), and a light transparent structure 150 (FIG. 2A). The reflective structure 120 is disposed on the display substrate 110. As shown in FIG. 1, the reflective structure 120 divides the surface of the display substrate 110 into multiple pixel areas 112. Each micro light-emitting element 130 is disposed in one of the pixel areas 112.

In the embodiment, the reflective structure 120 may simultaneously surround, for example, three micro light-emitting elements 130, but it is not limited thereto. Furthermore, the micro light-emitting elements 130 are, for example, micro light-emitting diodes, but the type of micro light-emitting elements 130 is not limited thereto.

As shown in FIG. 2A, the micro light-emitting element 130 has an upper surface 132 on the side away from the display substrate 110. The upper surface 132 is defined with a central area 134 and a peripheral area 136 surrounding the central area 134. The refractive structure 140 covers the peripheral area 136 of one of the micro light-emitting elements 130, and the refractive structure 140 exposes the central area 134 of the micro light-emitting element 130 to form a notch 142.

In the embodiment, the range of the peripheral area 136 of the upper surface 132 is determined by the position of the refractive structure 140. In other words, the area covered by the refractive structure 140 is the peripheral area 136, and the uncovered area is the central area 134. Certainly, the definition of the range of the peripheral area 136 is not limited thereto. For example, the peripheral area 136 may refer to the coverage area of the projection of the refractive structure 140 on the upper surface 132, not necessarily the area where it actually contacts and covers the upper surface 132.

As shown in FIG. 2A, the refractive structure 140 of the embodiment is a curved structure which has greater height at a position near the central axis X1 (FIG. 2A) of the micro light-emitting element 130 and has lower height at the periphery. The refractive structures 140 are filled between the corresponding micro light-emitting elements 130 and the reflective structure 120, as well as between the micro light-emitting elements 130 and the display substrate 110, respectively.

The refractive structure 140 has a contact surface 144 that contacts the light transparent structure 150 on the side away from the corresponding peripheral area 136, and an acute angle (included angle θ) is formed between each contact surface 144 and the upper surface 132 of the micro light-emitting element 130. Specifically, the side away from the peripheral area 136 refers to the upper surface (or outer surface) of the refractive structure 140 that contacts the light transparent structure 150 and forms an acute angle (included angle θ) with the upper surface 132 of the micro light-emitting element 130.

Furthermore, in the embodiment, the acute angle (included angle θ) refers to the angle between the tangent line at the interface point 145 where the contact surface 144 meets the reflective structure 120 and the extended plane of the upper surface 132. It can also be described as the included angle θ between the tangent line of the contact surface 144 at the interface point 145 and a plane parallel to the upper surface 132.

The refractive structure 140 is, for example, a light-guiding structure made of high refractive index photoresist, but it is not limited thereto. The refractive structure 140 may be fabricated by creating the contact surface 144 (for example, an arc surface or multi-segment inclined surface) through the hydrophilic/hydrophobic properties of materials, or methods such as reflow, ink-jet printing (IJP), etc., and then etching the center to form the notch 142.

In addition, the light transparent structure 150 covers the refractive structure 140 and the micro light-emitting element 130. The light transparent structure 150 fills the notch 142 and contacts the central area 134, and the refractive index of the light transparent structure 150 is lower than that of the refractive structure 140. In the embodiment, the light transparent structure 150 is, for example, an encapsulating colloid. Furthermore, in the longitudinal cross-section of the micro light-emitting element 130, a portion of the light transparent structure 150 is disposed between the contact surfaces 144 and the reflective structure 120.

As shown in FIG. 2A, the design of the notch 142 of the refractive structure 140 exposes the central area 134 of the micro light-emitting element 130. Due to the small included angle (divergence angle) between the ray L1 emitted from the central area 134 of the micro light-emitting element 130 and the vertical line, the ray L1 may directly emit light towards the upper side of the micro light-emitting element 130 without entering the refractive structure 140. Therefore, the display panel 100 may avoid the problem of rays L1 with very small divergence angles being refracted by the refractive structure 140 and diverging instead. At the same time, compared to the known technology of designing the refractive structure 140 to cover the entire surface, for rays L1 with the same divergence angle in the central area 134, the configuration with the notch 142 in the embodiment can reduce the difference in refractive index when the entire light path is refracted into the air (i.e., transitioning from the refractive structure 140 with higher refractive index to the light transparent structure 150 with lower refractive index). Therefore, when observing from the exterior of the display panel 100 (air side) towards the micro light-emitting element 130, the central area 134 of the embodiment can receive more rays at the same light reception angle.

For rays L2 with small divergence angles emitted from the peripheral area 136, the rays L2 will emit light towards the upper side of the micro light-emitting element 130 after undergoing a second refraction at the contact surface 144.

In the embodiment, the reflective structure 120 has a reflective wall 122 on the side adjacent to each micro light-emitting element 130. The reflective wall 122 includes a lower part 124 and an upper part 126. The lower part 124 is connected to the display substrate 110. The upper part 126 is connected to the lower part 124, and an absolute value of a slope of the upper part 126 relative to the upper surface 132 is smaller than an absolute value of a slope of the lower part 124 relative to the upper surface 132. For rays L3 with large divergence angles emitted from the central area 134, the rays L3 may enter the refractive structure 140, and after undergoing two refractions, they are directed to the upper part 126 of the reflective structure 120, finally reflecting upwards to improve the light extraction efficiency of the display panel 100.

Moreover, in the embodiment, the edge of the contact surface 144 of the refractive structure 140 is connected to the reflective structure 120. In the embodiment, in the longitudinal cross-section of the micro light-emitting element 130, the connection point (interface point 145) between the contact surface 144 and the reflective structure 120 is flush with the upper surface 132 of the micro light-emitting element 130, or slightly higher than the upper surface 132, i. e., positioned on the side of the upper surface 132 away from the display substrate 110.

The refractive structure 140 has a top part 146 away from the upper surface 132. In the direction from the top part 146 towards the reflective structure 120, each contact surface 144 includes a continuous curved surface, multiple curved surfaces with different centers of curvature, or multiple inclined surfaces with different slopes.

It is worth mentioning that in current display panels, the reflective structures used are mostly black matrix (BM) or higher-cost light reflective structures (white bank) to prevent crosstalk problems between pixels. However, due to the limitation of the penetration depth of photoresist liquid by yellow light exposure in the manufacturing process of the reflective structure, if the height of the reflective structure 120 needs to be increased, the process yield will significantly decrease. In the embodiment, since the refraction of ray L3 at the contact surface 144 is deflected downward, the height position where it is incident on the reflective structure 120 is lowered, thereby reducing the height requirement of the reflective structure 120. In other words, the display panel 100 can effectively reduce the height requirement of the reflective structure 120 through the configuration of the refractive structure 140 and the design of the contact surface 144, thereby improving the yield of the exposure process.

Referring first to FIG. 2C, in the embodiment, the absolute value of the tangent slope of the contact surface 144 relative to the upper surface 132 increases from the side adjacent to the notch 142 towards the side adjacent to the reflective structure 120.

Taking the left contact surface 144 as an example, the absolute value of the tangent slope increases from right to left in FIG. 2C. In other words, the tangent slope of the left contact surface 144 becomes steeper towards the left side (where the contact surface 144 connects with the reflective structure 120) of FIG. 2C and becomes gentler towards the right side (top part 146) of FIG. 2C. Certainly, the variation in the tangent slope of the contact surface 144 is not limited thereto.

The tangent slope of the contact surface 144 relative to the upper surface 132 has variations, which may automatically uniformize the deflection effect of rays. Specifically, the refractive structure 140 also has an inner side wall 148 connected to the upper surface 132. Under the premise that rays in the central area 134 will enter the refractive structure 140, when the divergence angle decreases, the incident angle of rays entering the refractive structure 140 from the inner side wall 148 will be enlarged instead. The causes the deflection angle of the rays after incident in the inner side wall 148 to increase correspondingly, resulting in an unfavorable increase in the incident position of the secondary refraction (i.e., the contact surface 144) within the refractive structure 140.

Therefore, the design where the tangent slope of the contact surface 144 relative to the upper surface 132 becomes gentler towards the top part 146 may automatically enlarge the incident angle of the secondary refraction of rays within the refractive structure 140 as the position of the incident point of rays entering the refractive structure 140 becomes higher. In other words, according to Snell's Law, since the sine function has the characteristic that the larger the incident angle, the greater the increase in the angle of refraction, the aforementioned design can effectively increase the degree of deflection of rays when they are emitted from the refractive structure 140, thereby increasing the probability of rays being reflected by the reflective structure 120.

FIG. 2B is a schematic diagram of one of the ray paths in FIG. 2A. Referring to FIG. 2B, it should be noted that in FIG. 2B, the solid line ray L4 represents the path of the ray refracted by the refractive structure 140, while the dashed ray L5 represents the original light extraction path without the refractive structure 140. Here, both rays L4 and L5 are drawn with the refractive indices of the light transparent structure 150 and the refractive structure 140 set to 1.5 and 1.7, respectively. Rays L4 and L5 are both emitted from the same position, and the included angle θ1 (divergence angle) with the vertical axis when leaving the upper surface 132 of the micro light-emitting element 130 is 42 degrees for both. Through simulation calculations, the included angle θ2 between the solid line ray L4 after being refracted twice by the refractive structure 140 and the vertical axis is 53 degrees. Compared to the ray L5 without the refractive structure 140, the ray L4 is deflected by an additional 11 degrees. In other words, compared to the ray L5, the incident position of the ray L4 in the upper layer part 126 may be lowered by 7.8%, to achieve the aforementioned purpose of reducing the height of the reflective structure 120.

In addition, for rays with divergence angles (included angle θ1) smaller than that of ray L5, the rays will have larger incident angles when incident on the inner side wall 148 and the contact surface 144. As mentioned earlier regarding the sine function, while the rays have enlarged incident angles, they will also obtain more significant deflection effects at the contact surface 144. Therefore, the design of the notch 142 of the refractive structure 140, combined with the slope variation of the contact surface 144, not only may reduce the height requirement of the reflective structure 120, but also has the effect of converging the landing points of rays with different divergence angles into a smaller area, thereby simplifying the design work of the shape of the upper layer part 126.

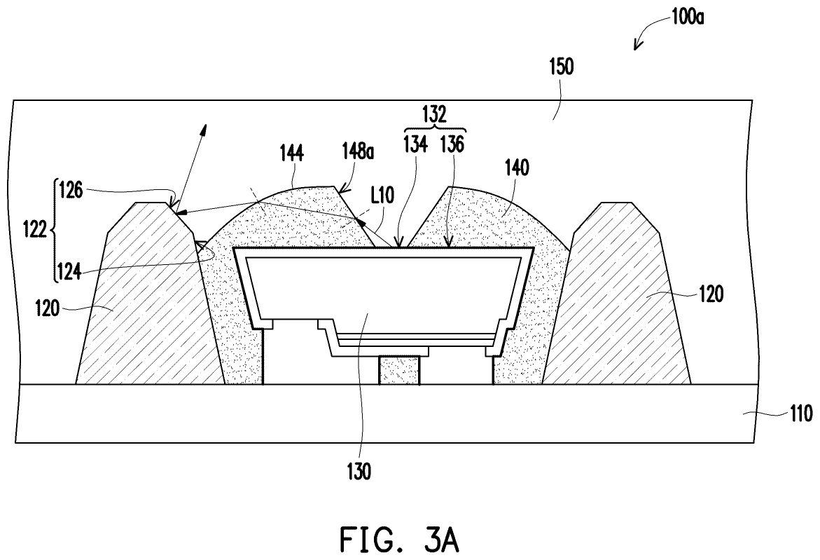

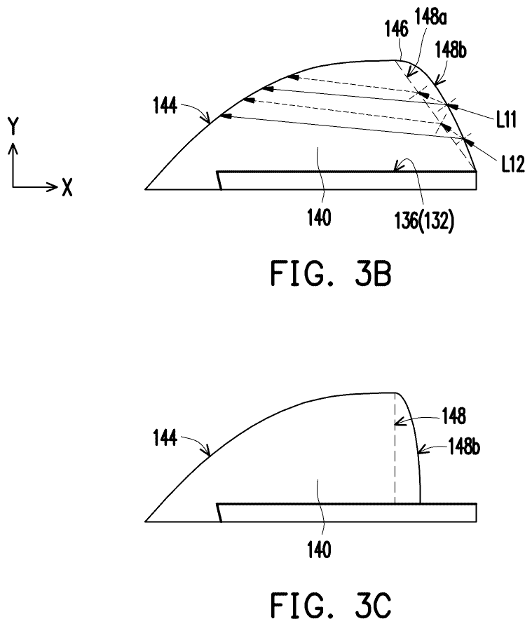

In the embodiment, the inner side wall 148 may be, for example, a vertical plane, but in other embodiments, such as the inner side wall 148b shown in FIG. 3B and FIG. 3C, it may also include at least one plane, one curved surface, or a combination thereof. Furthermore, the display panel 100 may adjust the height of the reflective structure 120 by adjusting the area ratio of the peripheral area 136 covered by the refractive structure 140 to the upper surface 132.

If the notch 142 of the refractive structure 140 is narrower, that is, the area ratio of the peripheral area 136 covered by the refractive structure 140 to the upper surface 132 is larger, in terms of ray L4, it means that the inner side wall 148 is closer to the center, causing the incident height of ray L4 entering the inner wall surface 148 to be lower, which may reduce the height requirement of the reflective structure 120.

On the other hand, a narrower notch 142 of the refractive structure 140 also means that more rays will enter the refractive structure 140. Since the rays from the central area will undergo double refraction when entering the refractive structure 140, causing the included angle between the rays leaving the refractive structure 140 and the vertical line to increase. Therefore, the height requirement of the reflective structure 120 may be reduced.

In the embodiment, the area ratio of the peripheral area 136 covered by the refractive structure 140 to the upper surface 132 may be 50% or more, for example, 50%˜80%, but it is not limited thereto. If the value of the area ratio of the peripheral area 136 covered by the refractive structure 140 to the upper surface 132 changes, it may affect the paths of rays with different divergence angles.

FIG. 2C is a partial enlarged view of FIG. 2A. Referring to FIG. 2C, for rays emitted from the peripheral area 136 covered by the refractive structure 140, the dashed boundary line B is the boundary line where rays may diverge or converge. If a ray is emitted along the boundary line B from the refractive structure 140, it will be emitted in a straight line without deflection. Ray L6 is a ray located on the right side of the boundary line B (that is to say, ray L6 has a smaller divergence angle), and after being refracted once by the refractive structure 140, it is emitted upwards, with ray L6 leaving the refractive structure 140 on the right side of the boundary line B.

Ray L7 is a ray located on the left side of the boundary line B (that is to say, ray L7 has a larger divergence angle), and after being refracted once by the refractive structure 140, it is directed towards the reflective structure 120, which reflects it towards the upper right. In other words, the large-angle ray L7 emitted from the peripheral area 136, after passing through the refractive structure 140 and being reflected by the reflective structure 120, will be deflected towards the center and converge towards the center.

For the large divergence angle ray L8 from the central area 134 that is not covered by the refractive structure 140, ray L8 may undergo double refraction through the refractive structure 140, and after being reflected by the reflective structure 120, it will be deflected towards the center and converge towards the center.

Ray L9, compared to ray L7, has a smaller divergence angle (included angle with the vertical line) when leaving the upper surface 132, but after being reflected by the reflective structure 120, the angle at which ray L9 deflects towards the upper right is actually larger than the angle at which ray L7 deflects towards the upper right. In other words, the included angle between ray L9 and the vertical line at the point where it is reflected by the reflective structure 120 increases, the ray L9 which is reflected by the reflective structure 120 located on the right side of the angle threshold line C, and the direction of ray L9 will pass over the center of the micro light emitting element 130, performing as a form of divergent light.

The deflection patterns of rays L6 and L9 are explained as below. For ray L6 located on the right side of the boundary line B, due to the refractive structure 140 receding from the center of the micro light emitting element 130 towards the reflective structure 120 to form the notch 142, when ray L6 is incident on the contact surface 144, the vast majority will be on the left side of the normal line, meaning that the emitted light of ray L6 will be deflected towards the center of the micro light emitting element 130. In other words, the presence of the notch 142 makes ray L6, with an extremely small divergence angle and directly incident from the peripheral area 136 to the contact surface 144, would otherwise be on the right side of the normal line and cause the divergence situation to be eliminated as much as possible. More specifically, the aforementioned situation may only occur in a small portion of the area adjacent to the top 146 on the right side of the boundary line B, but there is no chance for it to continue occurring in the area of the notch 142. As a result, the display panel 100 may avoid the defect in known technology where, due to the encapsulating colloid having a plano-convex shape, the degree of single deflection is insufficient, causing the rays to become more divergent when leaving the convex side of the encapsulating colloid.

For ray L9, the interface between the upper part 126 and the lower part 124 may be determined by the angle threshold line C after light reflection. Specifically, the angle threshold line C represents the critical line determining whether the ray passes over the center of the micro light emitting element 130 after being reflected by the reflective structure 120. Therefore, the display panel 100 may adjust the position of the interface between the upper part 126 and the lower part 124, for example, by moving the interface between the upper part 126 and the lower part 124 downward, so that ray L9 may be reflected by the upper part 126 with a gentler slope, thus reducing the deflection angle of ray L9 and directing it more upward to increase light extraction efficiency. Hence, the designer may first select the angle of the angle threshold line C to determine the position of the interface between the upper part 126 and the lower part 124.

As seen in FIG. 2C, regardless of whether it is ray L6 with a small divergence angle from the peripheral area 136, ray L7 with a large divergence angle from the peripheral area 136, or ray L8 with a large divergence angle from the central area 134, all may change their light paths through the refractive structure 140, or through both the refractive structure 140 and the reflective structure 120, to satisfy the requirement for small-angle light extraction.

FIG. 3A is a partial cross-sectional schematic view of a display panel according to another embodiment of the present invention. Referring to FIG. 3A, the main difference between FIG. 3A and FIG. 2A is that the shape of the inner wall 148a in FIG. 3A is different from the inner wall 148 in FIG. 2A. In the embodiment, the inner wall 148a of the refractive structure 140 is an inclined surface sloping upward. The angle of inclination of the inclined surface relative to the upper surface 132 may be, for example, 45° or more, but it is not limited thereto.

The design of the inner wall 148a as an inclined surface may significantly deflect the incident normal line while rays entering the refractive structure 140. For ray L10 with a large divergence angle emitted from the central area 134, the design of the inner wall 148a as an inclined surface may lower the height of the incident point of ray L10, thereby reducing the height at which subsequent refraction occurs.

Specifically, because the refractive index of the light transparent structure 150 is lower than that of the refractive structure 140, total internal reflection will not occur even if the incident angle of ray L10 at the inner wall 148a is enlarged. At the same time, compared to the vertical plane of the inner wall 148, the design of the inner wall 148a as an inclined surface may allow the ray to travel further within the refractive structure 140. As a result, the distance between the exit position of ray L10 at the contact surface 144 and the reflective structure 120 will be significantly reduced, thereby suppressing the problem of light divergence. Furthermore, by utilizing the difference in refractive indices, ray L10 may have the opportunity to refract towards the display substrate 110 at the contact surface 144, directly reducing the height requirement of the reflective structure 120.

FIG. 3B and FIG. 3C are partial cross-sectional schematic views of various refractive structures according to another embodiments of the present invention. It should be noted that FIG. 3B and FIG. 3C only illustratively depict partial refractive structures 140, while other structures are hidden.

Please first refer to FIG. 3B. The main difference between FIG. 3B and FIG. 3A is that the shape of the inner wall 148b in FIG. 3B is different from the inner wall 148a in FIG. 3A.

In the embodiment, the inner wall 148b of the refractive structure 140 includes a curved surface. In the direction from the top 146 towards the upper surface 132 (i.e., downwards in FIG. 3B), the absolute value of the tangent slope of the inner wall 148b relative to the upper surface 132 increases from the top 146 towards the +X direction (i.e., the slope of the inner wall 148 on the left side increases towards the bottom of FIG. 3C). In the embodiment, from the top to the bottom of FIG. 3B, the trend of change in the tangent slope of the inner wall 148b is opposite to the trend of change in the tangent slope of the contact surface 144.

In FIG. 3B, the solid line portion of ray L11 indicates the refraction path of ray L11 when the inner wall 148b is a curved surface, while the dashed line portion indicates the refraction path of ray L11 when the inner wall 148a is an inclined surface. Similarly, the solid line portion of ray L12 indicates the refraction path of ray L12 when the inner wall 148b is a curved surface, while the dashed line portion indicates the refraction path of ray L12 when the inner wall 148a is an inclined surface.

By comparing the solid line portion and dashed line portion of ray L11, and comparing the solid line portion and dashed line portion of ray L12, it can be observed that for rays with the same divergence angle, due to the difference between the curved surface and inclined surface of the inner wall 148b, when the inner wall 148b is a curved surface, the normal line of the incident surface of the refractive structure 140 is deflected while the rays entering and exiting the refractive structure 140, causing both the incident angle and the refraction angle to decrease. This may further extend the optical path, resulting in a lower position of the rays when leaving the refractive structure 140, thereby reducing the height requirement of the reflective structure 120 (FIG. 3A).

Please refer to FIG. 3C. The main difference between FIG. 3C and FIG. 2A is that in the embodiment, the inner wall 148c of the refractive structure 140 includes a curved surface. Similarly, the inner wall 148c of the embodiment, compared to the vertical plane of the inner wall 148 as shown in FIG. 2A, may also achieve the aforementioned effects.

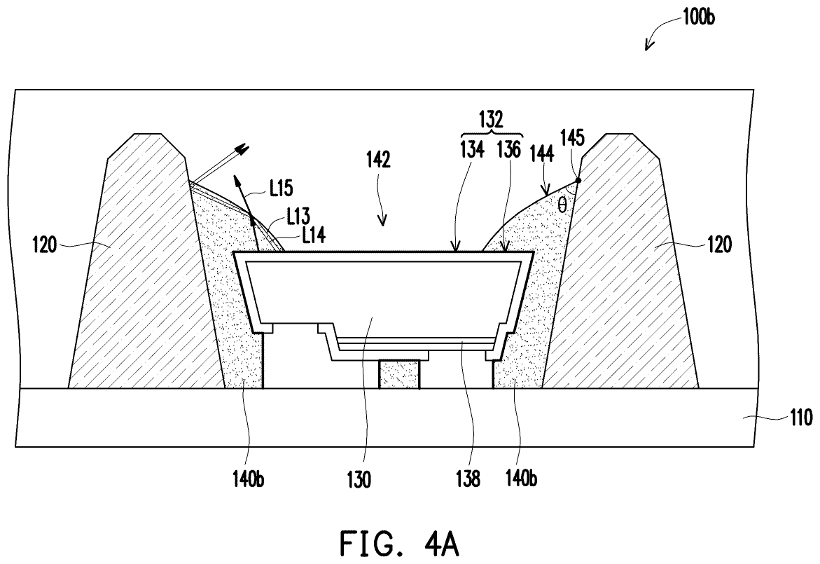

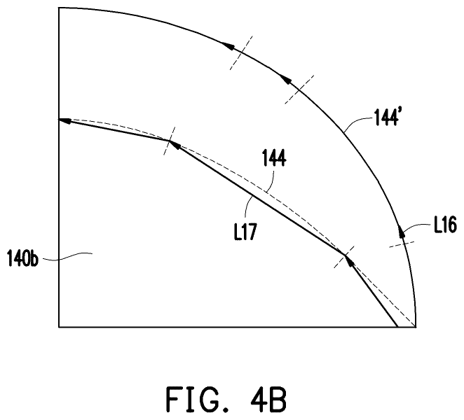

FIG. 4A is a partial cross-sectional schematic view of a display panel according to another embodiment of the present invention. Please refer to FIG. 4A. The main difference between the display panel 100b in FIG. 4A and the display panel 100 in FIG. 2A is the shape of the refractive structure 140b.

In the embodiment, the type of the refractive structure 140b is that a portion of the refractive structure 140b near the central axis (as shown in FIG. 2A) of the micro light emitting element 130 is lower and a portion of the refractive structure 140b near the reflective structure 120 is higher. Moreover, the height of the refractive structure 140b may be equal to or lower than the height of the reflective structure 120.

As shown in FIG. 4A, the refractive structure 140b covers a portion of the surface of the reflective structure 120. Here, in the design of the embodiment, compared to the aforementioned FIG. 2A or FIG. 3A, the rays only undergo their first refraction at the contact surface 144 after being reflected by the reflective structure 120. In other words, the rays leaving the peripheral area 136 are mainly transmitted to the reflective structure 120 within the refractive structure 140b through the mechanism of total internal reflection.

In the embodiment, the thickness of the refractive structures 140b in the direction perpendicular to the display substrate 110 (the up-down direction in FIG. 4A) increases from the side adjacent to the notch 142 towards the side adjacent to the reflective structure 120. Furthermore, the absolute value of the tangent slope of the contact surface 144 relative to the upper surface 132 decreases from the side adjacent to the notch 142 towards the side adjacent to the reflective structure 120 (that is, the tangent slope of the contact surface 144 on the left side decreases towards the left side of FIG. 4A).

For rays L13 and L14 with large divergence angles (e.g., above 60 degrees) from the peripheral area 136 of the micro light emitting element 130, such a design of the refractive structure 140b may have a light pattern optimization effect. Specifically, by utilizing the shape design of concave or convex lenses (or other multi-angled prisms) and the principle of total internal reflection, the rays L13 and L14 with large divergence angles from the peripheral area 136 of the micro light emitting element 130 are guided by the refractive structure 140b to a very small area of the reflective structure 120 (near the top 146 of the refractive structure 140b). Then, the rays L13 and L14 may be guided in similar directions and emitted upwards by the reflective structure 120 (which may have a single slope, but it is not limited thereto).

Moreover, since the refractive index of the micro light emitting element 130 is generally greater than the refractive index of common materials used for the refractive structure 140b, the proportion of rays L15 emitted from the peripheral area 136 with very small divergence angles is relatively low. Furthermore, because the types of rays L15 have smaller incident angles when incident on the contact surface 144, the degree of divergence after being refracted by the refractive structure 140b is also slight, and thus has little impact on the light extraction efficiency.

In addition, compared to the light pattern of the refractive structures 140b in FIG. 2A and FIG. 3A to FIG. 3C, which guide the large divergence angle rays from the central area to converge towards the central axis, the refractive structure 140b in the embodiment hardly deflects or interferes with the rays from the central area 134. In other words, the optical effect of the embodiment mainly focuses on converging the divergent light lost from the peripheral area 136, and making the visual brightness change of the display panel 100b smoother at different viewing angles. In other words, FIG. 2A, FIG. 3A, and FIG. 4A all can achieve good light extraction efficiency performance, with the main difference being in their design orientations.

FIG. 4B is a schematic diagram illustrating the light paths of the refractive structure in FIG. 4A comparing different curved types of contact surfaces. Please refer to FIG. 4B, if the contact surface 144′ is a part of a perfect circle (such as ¼ circular arc), then the ray L16 at the critical angle may be guided along the tangent of the circular arc to the reflective structure 120 (FIG. 4A).

In FIG. 4B, the contact surface 144 of FIG. 4A is represented by a dashed line. The tangent slope of the contact surface 144 becomes more gradual towards the top, causing the normal line of the incident ray L17 at the contact surface 144 of the refractive structure 140b to rotate counterclockwise to a greater degree. As mentioned earlier, due to the refractive indices of various materials, rays incident on the peripheral area 136 usually have larger divergence angles. Assuming that total internal reflection occurs at the first incident position of ray L17 in

FIG. 4B, the second and third segments of the ray after reflection also have a high probability of continuing to undergo total internal reflection. Specifically, because the tangent slope of the contact surface 144 becomes gradual towards left side more rapidly than a perfect circle (i.e., contact surface 144′), meaning that the contact surface 144 has a surface at a lower position than the contact surface 144′, this may ensure that the ray L17 is incident on the contact surface 144 again, thereby allowing multiple transmissions within the refractive structure 140b.

For rays emitted from the peripheral area 136 and satisfying the total internal reflection condition (such as ray L17), due to the aforementioned gradual change in tangent slope also causing a decrease in the incident angle of the reflected light, in order to ensure that subsequent incident angles are all greater than or equal to the critical angle, there exists an upper limit value to the rate at which the tangent slope of the contact surface 144 relative to the upper surface 132 becomes gradual as the position of the contact surface 144 changes. In other words, the allowable amount of change in the absolute value of the tangent slope at any point on the contact surface 144 is related to the position of that point on the contact surface 144. Here, the amount of change satisfies

$$\frac{dK}{\partial L} \leq \frac{{n}_{1} sin {θ}_{1} - {n}_{2}}{{n}_{1} L}$$

wherein n1 is the refractive index of the refractive structure 140b, n2 is the refractive index of the light transparent structure 150, θ1 is the critical angle for total internal reflection when rays enter the light transparent structure 150 from the refractive structure 140b, L is a path length between an incident position on the contact surface 144 and the upper surface 132 when a ray is incident from the contact surface 144 at the peripheral area 136 and undergoes total internal reflection, dK is an amount of slope reduction at each point (i.e., a position dL on the path length L) as the path length L increases, and the larger the path length L corresponding to each position dL, the smaller the allowable amount of slope reduction for that position dL.

More specifically, K refers to the total change amount of slope from the upper surface 132 to the incident points of rays on the contact surface 144, that is the integral sum of all dk quantities along the contact surface 144 from the upper surface 132 to the incident points of rays.

The aforementioned formula indicates that when the path length (L) between the incident position of the ray on the contact surface 144 and the upper surface 132 is known, the landing point of the ray after reflection is also necessarily known. dK/dL represents the upper limit value of the slope which is continuously and gradually reduced at that landing point position.

In other words, when the refractive index (n1) of the refractive structure 140b is greater than the refractive index (n2) of the light transparent structure 150, as the path length (L) between the incident position on the contact surface 144 and the upper surface 132 increases, the amount of slope reduction (K) of the contact surface 144 will become smaller. When the amount of slope reduction (K) is less than or equal to the aforementioned formula, the light-guiding state of total internal reflection within the refractive structure 140b may continue to occur.

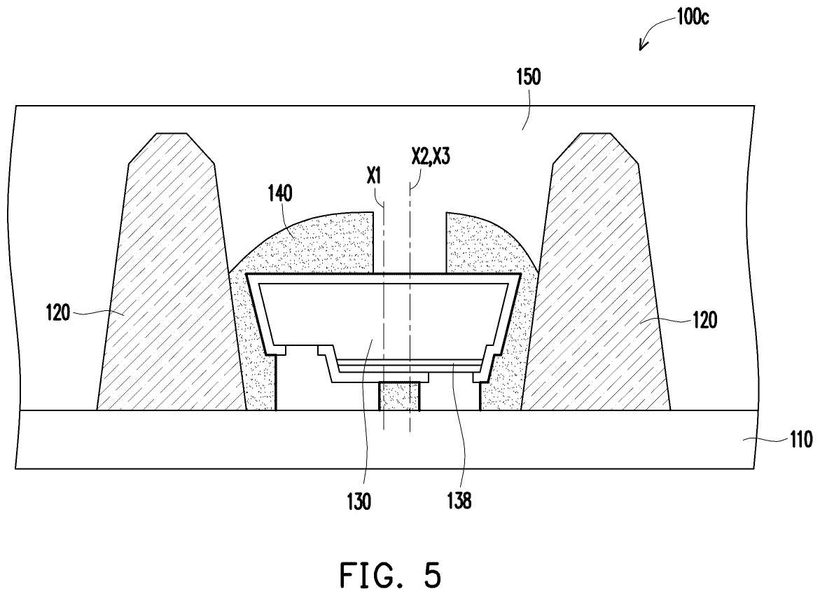

FIG. 5 is a partial cross-sectional schematic view of a display panel according to another embodiment of the present invention. Referring to FIG. 5, in the embodiment, the micro light emitting element 130 of the display panel 100c has a light emitting layer 138, and in the longitudinal cross-section of the micro light emitting element 130, a central axis X1 of the micro light emitting element 130 in a direction perpendicular to the display substrate 110 (up-down direction) does not coincide with a central axis X2 of the light emitting layer 138 in the direction perpendicular to the display substrate 110.

The main difference between the display panel 100c in FIG. 5 and the display panel 100 in FIG. 2A is that in FIG. 2A, a central axis X3 of the central area 134 of the micro light emitting element 130 is located between the central axis X1 of the micro light emitting element 130 and the central axis X2 of the light emitting layer 138.

In the embodiment, the central axis X3 of the central area 134 of the micro light emitting element 130 coincides with the central axis X2 of the light emitting layer 138. As a result, the central axis X3 of the central area 134 may be shifted to the central axis X2 of the light emitting layer 138, further modifying the light pattern of the micro light emitting element 130, thereby making the light pattern symmetrical.

In summary, the notch design of the refractive structure in the display panel of the present invention may allow rays emitted from the central area of the micro light emitting element, if rays having a very small divergence angle, not to enter the refractive structure, thereby avoiding the problem of rays with very small divergence angles being refracted by the refractive structure and diverging instead. Furthermore, the aforementioned configuration may allow rays with large divergence angles in the central area to enter the refractive structure, causing the rays to undergo secondary refraction in the refractive structure before being emitted towards the reflective structure, which may lower the height position at which the rays are incident on the reflective structure, thereby reducing the height requirements for the reflective structure. In addition, the light reflected by the reflective structure may be emitted towards the front of the micro light emitting element, thus improving the light extraction efficiency. As the light extraction efficiency of each micro light emitting element in the display panel is effectively improved, the uniformity of light extraction from the display panel is consequently increased.

What is claimed is:

1. A display panel, comprising:
a display substrate;
a reflective structure, disposed on the display substrate, and the reflective structure divides a surface of the display substrate into a plurality of pixel areas;
a plurality of micro light emitting elements, each of the micro light emitting elements is disposed in one of the pixel areas, and each of the micro light emitting elements has an upper surface on a side away from the display substrate, the upper surface defines a central area and a peripheral area surrounding the central area;
a plurality of refractive structures, each of the refractive structures covers the peripheral area of one of the micro light emitting elements, and exposes the central area of the micro light emitting element therein to form a notch; and
a light transparent structure, covering the refractive structures and the micro light emitting elements, the light transparent structure fills the notch of each of the refractive structures and contacts the central area of each of the micro light emitting elements, and a refractive index of the light transparent structure is smaller than a refractive index of the refractive structure;
wherein each of the refractive structures has a contact surface contacting the light transparent structure on a side away from the corresponding peripheral area, and an acute angle is included between the contact surface of each of the refractive structures and the upper surface of the corresponding micro light emitting element.

2. The display panel as claimed in claim 1, wherein the reflective structure has a reflective wall on a side adjacent to each of the micro light emitting elements, the reflective wall comprising:
a lower part, connected to the display substrate;
an upper part, connected to the lower part, and an absolute value of a slope of the upper part relative to the upper surface is smaller than an absolute value of a slope of the lower part relative to the upper surface.

3. The display panel as claimed in claim 1, wherein the refractive structures fill between the micro light emitting elements and the reflective structure, and between the micro light emitting elements and the display substrate, respectively.

4. The display panel as claimed in claim 1, wherein an edge of the contact surface of each of the refractive structures is connected to the reflective structure, and each of the refractive structures has a top part away from the corresponding upper surface, in a direction from the top part towards the reflective structure, the contact surface of each of the refractive structures comprises a continuous curved surface, a plurality of curved surfaces with different centers of curvature, or a plurality of inclined surfaces with different slopes.

5. The display panel as claimed in claim 4, wherein an absolute value of a tangent slope of the contact surface of each of the refractive structures relative to the corresponding upper surface increases from a side adjacent to the notch towards a side adjacent to the reflective structure.

6. The display panel as claimed in claim 4, wherein in a longitudinal cross-section of the micro light emitting elements, a part of the light transparent structure is disposed between the contact surface of each of the refractive structures and the reflective structure.

7. The display panel as claimed in claim 4, wherein in a longitudinal cross-section of the micro light emitting elements, a connection between the contact surface of each of the refractive structures and the reflective structure is flush with the upper surface of the corresponding micro light emitting element, or is located on a side of the upper surface away from the display substrate.

8. The display panel as claimed in claim 1, wherein each of the refractive structures has a top part away from the upper surfaces and an inner side wall connected to the corresponding upper surface, each of the inner side walls comprises at least one plane, one curved surface or a combination thereof.

9. The display panel as claimed in claim 8, wherein in a direction from the top part towards the corresponding upper surface, an absolute value of a tangent slope of the inner side wall relative to the corresponding upper surface increases from the top part towards the upper surface.

10. The display panel as claimed in claim 1, wherein an area ratio of the peripheral area covered by each of the refractive structures to the upper surface is 50% or more.

11. The display panel as claimed in claim 1, wherein each of the refractive structures covers a part of the surface of the reflective structure, and thicknesses of the refractive structures in a direction perpendicular to the display substrate increases from a side adjacent to the notch towards a side adjacent to the reflective structure.

12. The display panel as claimed in claim 11, wherein an absolute value of a tangent slope of the contact surface of each of the refractive structures relative to the corresponding upper surface decreases from a side adjacent to the notch towards a side adjacent to the reflective structure.

13. The display panel as claimed in claim 12, wherein the absolute value of the tangent slope of the contact surface of each of the refractive structures relative to the corresponding upper surface has a variation amount, and the variation amount satisfies
$$\frac{dK}{\partial L} \leq \frac{{n}_{1} sin {θ}_{1} - {n}_{2}}{{n}_{1} L} ,$$
wherein n1 is the refractive index of the refractive structure, n2 is the refractive index of the light transparent structure, θ1 is a critical angle of total reflection when a ray is incident from the refractive structure to the light transparent structure, L is a path length between an incident position dL on the contact surface and the upper surface when the ray is incident from the contact surface at the peripheral area and undergoes total reflection, dK is an amount of slope reduction of the contact surface at the incident position dL as the path length L increases.

14. The display panel as claimed in claim 1, wherein each of the micro light emitting elements has a light emitting layer, and in a longitudinal cross-section of each of the micro light emitting elements, a central axis of the micro light emitting element in a direction perpendicular to the display substrate does not coincide with a central axis of the light emitting layer in the direction perpendicular to the display substrate.

15. The display panel as claimed in claim 14, wherein a central axis of the central area of the micro light emitting element is located between the central axis of the micro light emitting element and the central axis of the light emitting layer, or the central axis of the central area of the micro light emitting element coincides with the central axis of the light emitting layer.
